(19) United States
(12) Patent Application Publication
(10) Pub. No.: US 2024/0206174 A1
(43) Pub. Date: Jun. 20, 2024

(54) SEMICONDUCTOR DEVICE AND ELECTRONIC SYSTEM INCLUDING THE SAME

(71) Applicant: Samsung Electronics Co., Ltd., Suwon-si (KR)

(72) Inventors: Seulye KIM, Suwon-si (KR); Sunhwa LIM, Suwon-si (KR); Moohyun KIM, Suwon-si (KR); Sunggil KIM, Suwon-si (KR); Yunji PARK, Suwon-si (KR); Younghwan JO, Suwon-si (KR)

(73) Assignee: Samsung Electronics Co., Ltd., Suwon-si (KR)

(21) Appl. No.: 18/498,696

(22) Filed: Oct. 31, 2023

(30) Foreign Application Priority Data
Dec. 19, 2022 (KR) 10-2022-0178413

(51) Int. Cl. H10B 43/27; H01L 25/065; H10B 41/10; H10B 41/27; H10B 41/35; H10B 43/10; H10B 43/35; H10B 80/00

(52) U.S. Cl. CPC H10B 43/27; H01L 25/0652; H10B 41/10; H10B 41/27; H10B 41/35; H10B 43/10; H10B 43/35; H10B 80/00; H01L 2225/06524

(57) ABSTRACT

A semiconductor device may include a gate stack including insulating and conductive patterns, which are alternately stacked on top of each other, a memory channel structure penetrating the gate stack, a selection line structure on the gate stack, and a selection channel structure penetrating the selection line structure. The selection channel structure may include a selection channel layer, which is electrically connected to the memory channel layer, and a selection insulating structure, which encloses the selection channel layer. The selection channel layer may include a connecting portion on the memory channel structure and a pillar portion on the connecting portion, and an average size of grains in the connecting portion may be less than an average size of grains in the pillar portion.

### CROSS-REFERENCE TO RELATED APPLICATIONS

This U.S. non-provisional patent application claims priority under 35 U.S.C. § 119 to Korean Patent Application No. 10-2022-0178413, filed on Dec. 19, 2022, in the Korean Intellectual Property Office, the entire contents of which are hereby incorporated by reference.

### BACKGROUND

Various example embodiments relate to a semiconductor device and/or an electronic system including the same, and in particular, to a semiconductor device including bit lines, which are overlapped with each other, and/or an electronic system including the same.

Due to their small-sized, multifunctional, and/or low-cost characteristics, semiconductor devices are being esteemed as important elements in the electronics industry. The semiconductor devices are classified into a semiconductor memory device for storing data, a semiconductor logic device for processing data, and a hybrid semiconductor device including both of memory and logic elements.

With the recent trend of high speed and low power consumption of electronic devices, semiconductor devices in the electronic devices are also required or expected to have high operating speeds and/or low operating voltages, and in order to satisfy these expectations, it is necessary or desirable to increase an integration density of the semiconductor device. However, as the integration density of the semiconductor device increases, the semiconductor device may suffer from deterioration in electrical characteristics and/or production yield. Accordingly, many studies are being conducted to improve the electrical characteristics and production yield of the semiconductor device.

### SUMMARY

Various example embodiments provide a semiconductor device with improved electrical and/or reliability characteristics, and/or an electronic system including the same.

According to various example embodiments of inventive concepts, a semiconductor device may include a gate stack including insulating and conductive patterns, which are alternately stacked on top of each other, a memory channel structure penetrating the gate stack, a selection line structure on the gate stack, and a selection channel structure penetrating the selection line structure. The memory channel structure may include an insulating capping layer, a memory channel layer enclosing the insulating capping layer, and a memory layer enclosing the memory channel layer. The selection channel structure may include a selection channel layer electrically connected to the memory channel layer, and a selection insulating structure enclosing the selection channel layer. The selection channel layer may include a connecting portion on the memory channel structure and a pillar portion on the connecting portion, and an average size of grains in the connecting portion may be smaller than an average size of grains in the pillar portion.

Alternatively or additionally according to various example embodiments of inventive concepts, a semiconductor device may include a gate stack including insulating and conductive patterns, which are alternately stacked on top of each other, a memory channel structure penetrating the gate stack, a selection line structure on the gate stack, and a selection channel structure penetrating the selection line structure. The memory channel structure may include an insulating capping layer, a memory channel layer enclosing the insulating capping layer, and a memory layer enclosing the memory channel layer. The selection channel structure may include a selection channel layer electrically connected to the memory channel layer, and a selection insulating structure enclosing the selection channel layer. The selection channel layer may include a connecting portion on the memory channel structure and a pillar portion on the connecting portion. The pillar portion may overlap with a center of the selection channel structure, when viewed in a plan view.

According to various example embodiments of inventive concepts, an electronic system may include a main substrate, a semiconductor device on the main substrate, and a controller on the main substrate and electrically connected to the semiconductor device. The semiconductor device may include a gate stack including insulating and conductive patterns, which are alternately stacked on top of each other, a memory channel structure penetrating the gate stack, a selection line structure on the gate stack, and a selection channel structure penetrating the selection line structure. The memory channel structure may include an insulating capping layer, a memory channel layer enclosing the insulating capping layer, and a memory layer enclosing the memory channel layer. The selection channel structure may include a selection channel layer electrically connected to the memory channel layer, and a selection insulating structure enclosing the selection channel layer. The selection channel layer may include a connecting portion on the memory channel structure and a pillar portion on the connecting portion. The pillar portion may overlap with a center of the selection channel structure, when viewed in a plan view. A width of the connecting portion may be larger than a width of the pillar portion. The selection channel layer may include polysilicon, and an average size of grains in the connecting portion may be smaller than a mean size of grains in the pillar portion.

According to various example embodiments of inventive concepts, a method of fabricating a semiconductor device may include forming a stack including insulating and sacrificial layers, which are alternately stacked on top of each other, forming a memory channel structure to penetrate the stack, forming a gate stack by replacing the sacrificial layer with a conductive pattern, forming a selection line structure on the gate stack, forming a selection insulating structure enclosed by the selection line structure, and forming a selection channel layer enclosed by the selection insulating structure. The forming of the selection channel layer may include forming a preliminary selection channel layer, which is enclosed by the selection insulating structure, and melting the preliminary selection channel layer.

### BRIEF DESCRIPTION OF THE DRAWINGS

FIG. 1A is a schematic diagram illustrating an electronic system including a semiconductor device according to various example embodiments of inventive concepts.

FIG. 1B is a perspective view schematically illustrating an electronic system including a semiconductor device according to various example embodiments of inventive concepts.

FIGS. 1C and 1D are sectional views, each of which schematically illustrates a semiconductor package according to various example embodiments of inventive concepts.

FIG. 2A is a plan view illustrating a semiconductor device according to various example embodiments of inventive concepts.

FIG. 2B is a sectional view taken along a line A-A′ of FIG. 2A.

FIG. 2C is an enlarged view of a portion ‘B’ of FIG. 2B.

FIGS. 3A, 3B, 3C, and 3D are diagrams illustrating a method of fabricating a semiconductor device, according to various example embodiments of inventive concepts.

FIG. 4 is an enlarged sectional view illustrating a semiconductor device according to various example embodiments of inventive concepts.

FIG. 5 is an enlarged sectional view illustrating a semiconductor device according to various example embodiments of inventive concepts.

### DETAILED DESCRIPTION

Various example embodiments of inventive concepts will now be described more fully with reference to the accompanying drawings, in which example embodiments are shown. Like reference numerals in the drawings denote like elements, and thus their description will be omitted.

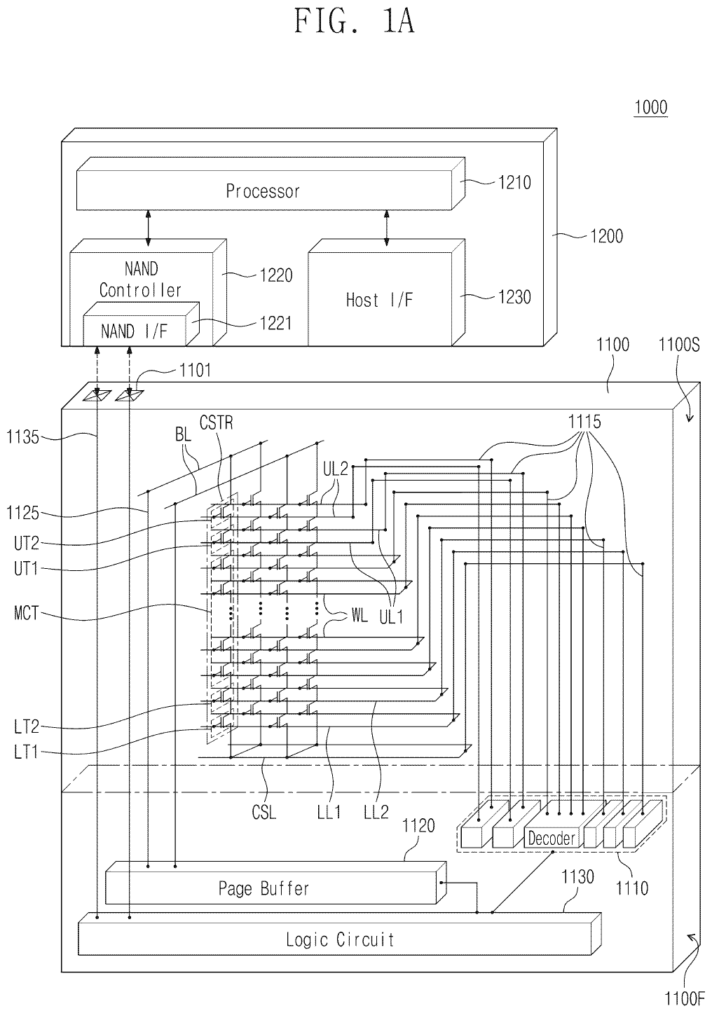

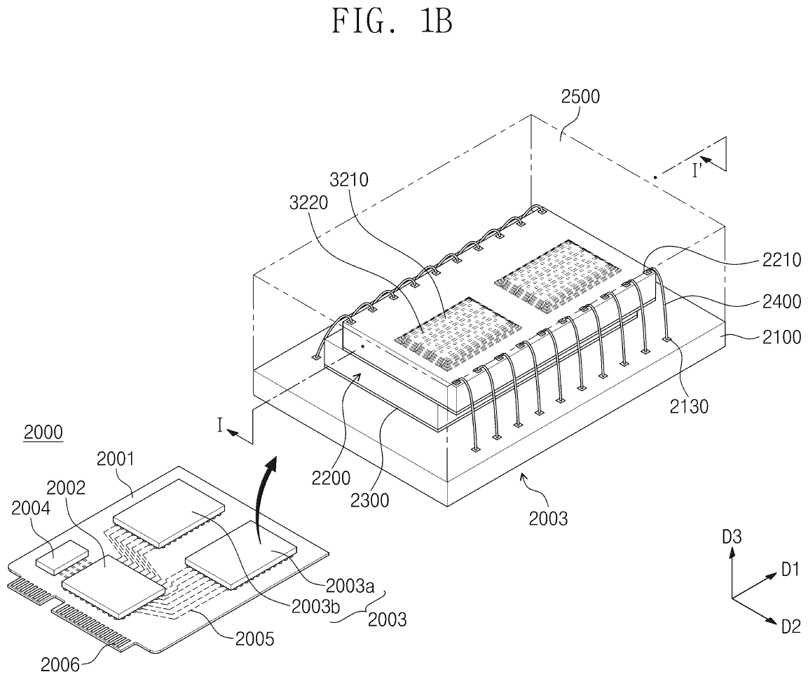

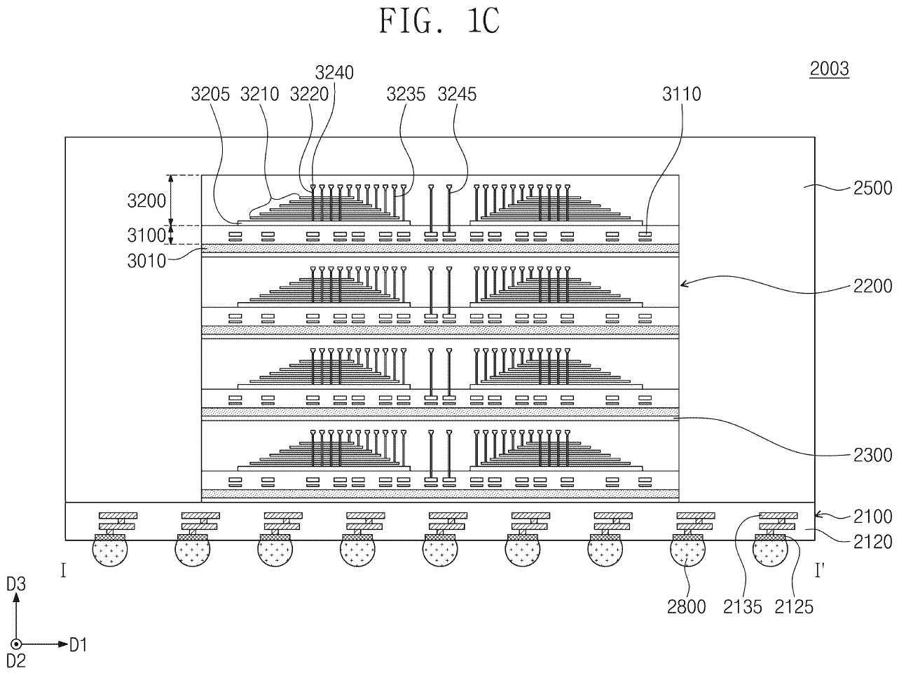

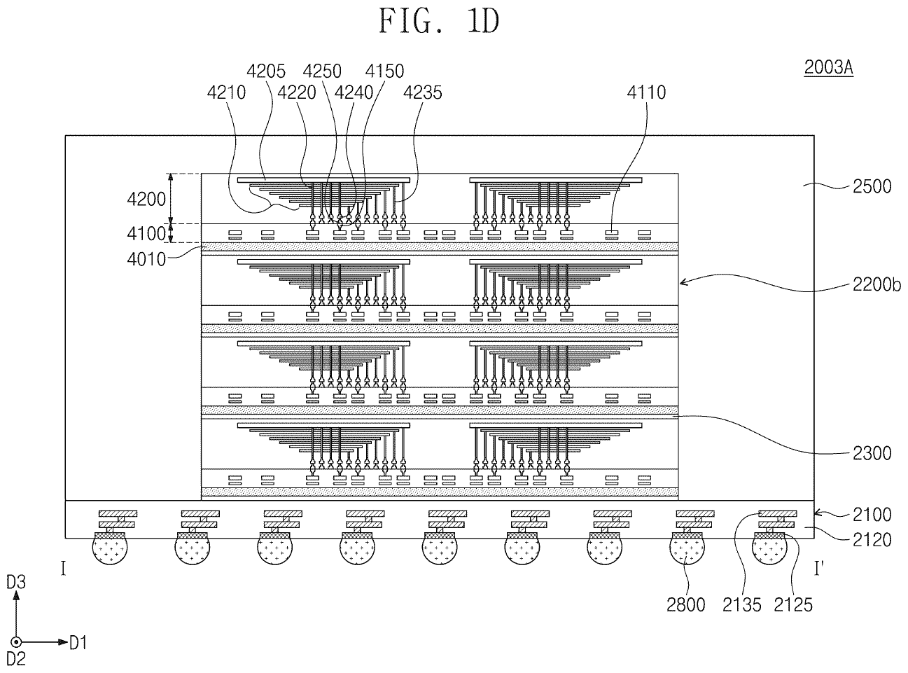

FIG. 1A is a schematic diagram illustrating an electronic system including a semiconductor device according to various example embodiments of inventive concepts.

Referring to FIG. 1A, an electronic system 1000 according to various example embodiments of inventive concepts may include a semiconductor device 1100 and a controller 1200, which is electrically connected to the semiconductor device 1100. The electronic system 1000 may be or may include or be included in a storage device including one or more semiconductor devices 1100 or an electronic device including the storage device. For example, the electronic system 1000 may be or include or be included in one or more of a solid state drive (SSD) device, a universal serial bus (USB), a computing system, a medical system, or a communication system, in which at least one semiconductor device 1100 is provided.

The semiconductor device 1100 may be or include or be included in a nonvolatile memory device and may be or include or be include in, for example, a NAND FLASH memory device. The semiconductor device 1100 may include a first structure 1100F and a second structure 1100S on the first structure 1100F. In various example embodiments, the first structure 1100F may be disposed beside the second structure 1100S. The first structure 1100F may be or may correspond to a peripheral circuit structure, which includes a decoder circuit 1110, a page buffer 1120, and a logic circuit 1130. The second structure 1100S may be or may correspond to a memory cell structure, which includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2, which are adjacent to the common source line CSL, upper transistors UT1 and UT2, which are adjacent to the bit line BL, and a plurality of memory cell transistors MCT, which are disposed between the lower transistors LT1 and LT2 and the upper transistors UT1 and UT2. The number of the lower transistors LT1 and LT2 and the number of the upper transistors UT1 and UT2 may be variously changed and may or may not be the same as each other, according to embodiments.

In various example embodiments, the upper transistors UT1 and UT2 may include a string selection transistor, and the lower transistors LT1 and LT2 may include a ground selection transistor. The gate lower lines LL1 and LL2 may be respectively used as gate electrodes of the lower transistors LT1 and LT2. The word lines WL may be used as gate electrodes of the memory cell transistors MCT, respectively, and the gate upper lines UL1 and UL2 may be used as gate electrodes of the upper transistors UT1 and UT2, respectively.

The common source line CSL, the first and second gate lower lines LL1 and LL2, the word lines WL, and the first and second gate upper lines UL1 and UL2 may be electrically connected to the decoder circuit 1110 through first connection lines 1115, which extend from the first structure 1100F into the second structure 1100S. The bit lines BL may be electrically connected to the page buffer 1120 through second connection lines 1125, which extend from the first structure 1100F into the second structure 1100S.

In the first structure 1100F, the decoder circuit 1110 and the page buffer 1120 may be configured to perform one or more control operations on at least selected one of the memory cell transistors MCT. The decoder circuit 1110 and the page buffer 1120 may be controlled by the logic circuit 1130. The semiconductor device 1100 may communicate with the controller 1200 through an input/output pad 1101, which is electrically connected to the logic circuit 1130. The input/output pad 1101 may be electrically connected to the logic circuit 1130 through an input/output connection line 1135, which is extended from the first structure 1100F to the second structure 1100S.

The controller 1200 may include a processor 1210, a NAND controller 1220, and a host interface 1230. In various example embodiments, the electronic system 1000 may include a plurality of semiconductor devices 1100, and in this case, the controller 1200 may be configured to control all or at least portions of the semiconductor devices 1100.

The processor 1210 may control overall operations of the electronic system 1000 including the controller 1200. The processor 1210 may be operated based on a specific firmware and may control the NAND controller 1220 to access the semiconductor device 1100. The NAND controller 1220 may include a NAND interface 1221 which is used for communication with the semiconductor device 1100. The NAND interface 1221 may be used to transmit and/or to receive control commands to control the semiconductor device 1100, data to be written in or read from the memory cell transistors MCT of the semiconductor device 1100, and so forth. The host interface 1230 may be configured to allow for communication between the electronic system 1000 and an external host. When a control command is received from the external host through the host interface 1230, the processor 1210 may control the semiconductor device 1100 in response to the control command.

FIG. 1B is a perspective view schematically illustrating an electronic system including a semiconductor device, according to various example embodiments of inventive concepts.

Referring to FIG. 1B, an electronic system 2000 according to various example embodiments of inventive concepts may include a main substrate 2001 and a controller 2002, one or more semiconductor packages 2003, and a memory device such as a volatile memory device, e.g., a DRAM 2004, which are mounted on the main substrate 2001. The semiconductor package 2003 and the DRAM 2004 may be connected to the controller 2002 and to each other by interconnection patterns 2005, which are formed in the main substrate 2001.

The main substrate 2001 may include a connector 2006, which includes a plurality of pins coupled to an external host. In the connector 2006, the number and/or the arrangement of the pins may depend on a communication interface between the electronic system 2000 and the external host. In various example embodiments, the electronic system 2000 may communicate with the external host, in accordance with one or more of various interfaces, such as one or more of universal serial bus (USB), peripheral component interconnect express (PCI-Express), serial advanced technology attachment (SATA), universal flash storage (UFS) M-PHY, or the like. In various example embodiments, the electronic system 2000 may be driven by an electric power, which is supplied from the external host through the connector 2006. The electronic system 2000 may further include a power management integrated circuit (PMIC) that is configured to distribute a power, which is supplied from the external host, to the controller 2002 and the semiconductor package 2003.

The controller 2002 may be configured to control a writing and/or reading operation on the semiconductor package 2003. The controller 2002 may help to improve an operation speed of the electronic system 2000.

The DRAM 2004 may be or may include or be included in a buffer memory that is configured to relieve technical difficulties caused by a difference in speed between the semiconductor package 2003, which serves as a data storage device, and an external host. In various example embodiments, the DRAM 2004 in the electronic system 2000 may serve as a cache memory and may be used as a storage space, which is used to temporarily store data during a control operation on the semiconductor package 2003. In the case where the electronic system 2000 includes the DRAM 2004, the controller 2002 may further include a DRAM controller for controlling the DRAM 2004, in addition to a NAND controller for controlling the semiconductor package 2003.

The semiconductor package 2003 may include a number of packages, such as first and second semiconductor packages 2003a and 2003b which are spaced apart from each other. Each of the first and second semiconductor packages 2003a and 2003b may be a semiconductor package including a plurality of semiconductor chips 2200. Each of the first and second semiconductor packages 2003a and 2003b may include a package substrate 2100, the semiconductor chips 2200 which are provided on the package substrate 2100, adhesive layers 2300 which are respectively disposed in bottom surfaces of the semiconductor chips 2200, a connection structure 2400 which electrically connects the semiconductor chips 2200 to the package substrate 2100, and a molding layer 2500 which is provided on the package substrate 2100 to cover the semiconductor chips 2200 and the connection structure 2400.

The package substrate 2100 may be or may include a printed circuit board, which includes package upper pads 2130; however, example embodiments are not limited thereto. Each of or at least some of the semiconductor chips 2200 may include an input/output pad 2210. The input/output pad 2210 may correspond to the input/output pad 1101 of FIG. 1A. Each of or at least some of the semiconductor chips 2200 may include gate stacks 3210 and memory channel structures 3220. Each of or at least some of the semiconductor chips 2200 may include a semiconductor device.

In various example embodiments, the connection structure 2400 may be a bonding wire electrically connecting the input/output pad 2210 to the package upper pads 2130. Thus, in each of the first and second semiconductor packages 2003a and 2003b, the semiconductor chips 2200 may be electrically connected to each other in a bonding wire manner and may be electrically connected to the package upper pads 2130 of the package substrate 2100. Alternatively or additionally, in each of the first and second semiconductor packages 2003a and 2003b, the semiconductor chips 2200 may be electrically connected to each other by a connection structure including through-silicon vias (TSVs), not by or in addition to the connection structure 2400 provided in the form of bonding wires.

In various example embodiments, the controller 2002 and the semiconductor chips 2200 may be included in a single package. In various example embodiments, the controller 2002 and the semiconductor chips 2200 may be mounted on an additional interposer substrate different from the main substrate 2001 and may be connected to each other through interconnection lines, which are provided in the interposer substrate.

FIGS. 1C and 1D are sectional views schematically illustrating semiconductor packages according to various example embodiments of inventive concepts. Each of FIGS. 1C and 1D schematically illustrates an example of the semiconductor package 2003 of FIG. 1B taken along a line I-I′ of FIG. 1B.

Referring to FIG. 1C, in the semiconductor package 2003, the package substrate 2100 may be or may include a printed circuit board. The package substrate 2100 may include a package substrate body portion 2120, package upper pads 2130 (e.g., of FIG. 1B) disposed on a top surface of the package substrate body portion 2120, lower pads 2125 disposed on and/or exposed through a bottom surface of the package substrate body portion 2120, and internal lines 2135 provided in the package substrate body portion 2120 to electrically connect the upper pads 2130 to the lower pads 2125. The upper pads 2130 may be electrically connected to the connection structures 2400 (e.g., of FIG. 1B). The lower pads 2125 may be connected to the interconnection patterns 2005 of the main substrate 2001 of the electronic system 2000, which is shown in FIG. 1B, through conductive connecting portions 2800.

Each of the semiconductor chips 2200 may include a semiconductor substrate 3010 and a first structure 3100 and a second structure 3200, which are sequentially stacked on the semiconductor substrate 3010. The first structure 3100 may include a peripheral circuit region provided with peripheral lines 3110. The second structure 3200 may include a common source line 3205, a gate stack 3210 on the common source line 3205, the memory channel structures 3220, which are provided to penetrate the gate stack 3210, bit lines 3240, which are electrically connected to the memory channel structures 3220, and gate contact plugs 3235, which are electrically connected to the word lines WL (e.g., see FIG. 1A) of the gate stack 3210.

Each of the semiconductor chips 2200 may be electrically connected to the peripheral lines 3110 of the first structure 3100 and may include a penetration line 3245, which is extended into the second structure 3200. The penetration line 3245 may be disposed outside the gate stack 3210. In various example embodiments, the penetration line 3245 may be provided to penetrate the gate stack 3210. Each of the semiconductor chips 2200 may further include the input/output pad 2210 of FIG. 1B.

Referring to FIG. 1D, in a semiconductor package 2003A, each of semiconductor chips 2200a may include a semiconductor substrate 4010, a first structure 4100 on the semiconductor substrate 4010, and a second structure 4200, which is disposed on the first structure 4100 and is bonded to the first structure 4100 by a wafer bonding method.

The first structure 4100 may include a peripheral circuit region, in which a peripheral line 4110 and first junction structures 4150 are provided. The second structure 4200 may include a common source line 4205, a gate stack 4210 between the common source line 4205 and the first structure 4100, memory channel structures 4220, which are provided to penetrate the gate stack 4210, bit lines 4240 electrically connected to the memory channel structures 4220, gate contact plugs 4235, which are electrically connected to the word lines WL of FIG. 1A of the gate stack 4210, respectively, and second junction structures 4250. For example, the second junction structures 4250 may be electrically connected to the memory channel structures 4220, respectively, through the bit lines 4240, which are electrically connected to the memory channel structures 4220. The first junction structures 4150 of the first structure 4100 and the second junction structures 4250 of the second structure 4200 may be bonded to each other. In

The semiconductor chips 2200 of FIG. 1C and the semiconductor chips 2200b of FIG. 1D may be electrically connected to each other by the connection structures 2400 of FIG. 1B, which are provided in the form of bonding wires. Alternatively or additionally, in various example embodiments, semiconductor chips, which are provided in the same semiconductor package as the semiconductor chips 2200 of FIG. 1C or the semiconductor chips 2200b of FIG. 1D, may be electrically connected to each other through a connection structure including the through-silicon vias (TSVs).

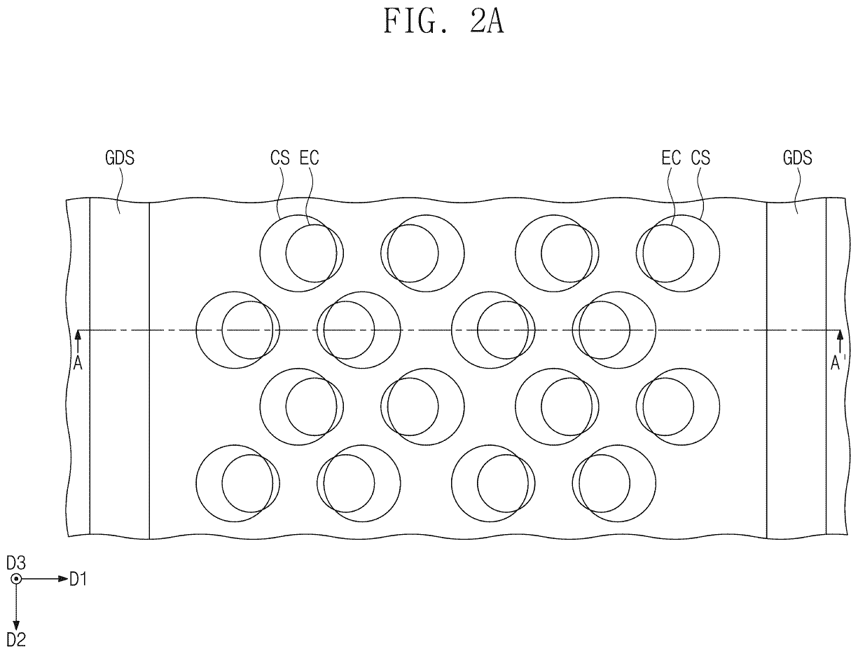

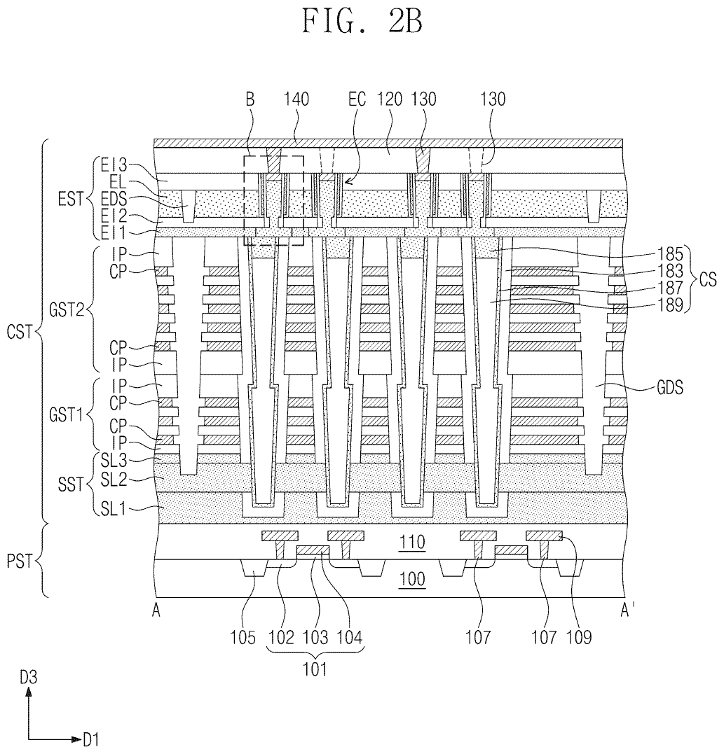

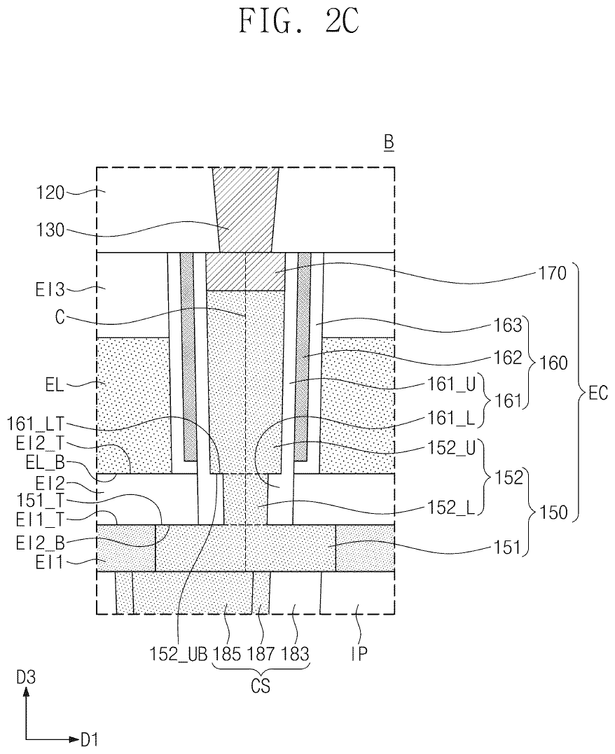

FIG. 2A is a plan view illustrating a semiconductor device according to various example embodiments of inventive concepts. FIG. 2B is a sectional view taken along a line A-A′ of FIG. 2A. FIG. 2C is an enlarged view of a portion ‘B’ of FIG. 2B.

Referring to FIGS. 2A and 2B, the semiconductor device may include a peripheral circuit structure PST and a memory cell structure CST on the peripheral circuit structure PST.

The peripheral circuit structure PST may include a substrate 100. The substrate 100 may be a plate-shaped structure that is extended parallel to a plane defined by a first direction D1 and a second direction D2. The first and second directions D1 and D2 may not be parallel to each other. In various example embodiments, the first and second directions D1 and D2 may be two different horizontal directions, which are orthogonal to each other. In various example embodiments, the substrate 100 may be a semiconductor substrate. As an example, the substrate 100 may be formed of or include one or more of silicon, germanium, silicon-germanium, GaP, or GaAs. In various example embodiments, the substrate 100 may be a silicon-on-insulator (SOI) substrate and/or a germanium-on-insulator (GOI) substrate.

The peripheral circuit structure PST may further include a peripheral circuit insulating layer 110 on the substrate 100. The peripheral circuit insulating layer 110 may include an insulating material. As an example, the peripheral circuit insulating layer 110 may be formed of or include an oxide material. In various example embodiments, the peripheral circuit insulating layer 110 may be composed of a plurality of insulating layers.

The peripheral circuit structure PST may further include a peripheral transistor 101. The peripheral transistor 101 may be provided between the substrate 100 and the peripheral circuit insulating layer 110. In various example embodiments, the peripheral transistor 101 may include source/drain regions 102, a gate electrode 104, and a gate insulating layer 103. The source/drain regions 102 may be formed by doping the substrate 100 with impurities such as one or more of boron, phosphorus, or arsenic. The gate electrode 104 may include a conductive material such as doped polysilicon and/or a metal. The gate insulating layer 103 may include an insulating material. Device isolation layers 105 may be provided in the substrate 100. The peripheral transistor 101 may be disposed between the device isolation layers 105. The device isolation layer 105 may be formed of or include an insulating material such as an oxide. In some example embodiments, the peripheral transistors 101 may be arranged such that the gate electrodes extend in the second direction D2; however, example embodiments are not limited thereto. For example, alternatively or additionally some peripheral transistors 101 may be arranged such that gate electrodes extend in the first direction D1.

The peripheral circuit structure PST may further include peripheral contacts 107 and peripheral conductive lines 109. The peripheral contact 107 may be connected to the peripheral transistor 101, and the peripheral conductive line 109 may be connected to the peripheral contact 107. The peripheral contact 107 and the peripheral conductive line 109 may be provided in the peripheral circuit insulating layer 110. The peripheral contact 107 and the peripheral conductive line 109 may be formed of or include at least one of conductive materials such as but not limited to doped polysilicon and/or metal.

The memory cell structure CST may include a source structure SST, a first gate stack GST1, a second gate stack GST2, memory channel structures CS, gate division structures GDS, a selection line structure EST, and selection channel structures EC, a cover insulating layer 120, bit line contacts 130, and bit lines 140.

The source structure SST may include a first source layer SL1 on the peripheral circuit structure PST, a second source layer SL2 on the first source layer SL1, and a third source layer SL3 on the second source layer SL2.

The first to third source layers SL1, SL2, and SL3 may include a conductive material. In various example embodiments, the first to third source layers SL1, SL2, and SL3 may be formed of or include polysilicon such as doped polysilicon. The second source layer SL2 may be a common source line.

The first gate stack GST1 may be provided on the source structure SST. The first gate stack GST1 may include insulating patterns IP and conductive patterns CP, which are alternately stacked on top of each other in a third direction D3. The third direction D3 may not be parallel to the first and second directions D1 and D2. As an example, the third direction D3 may be a vertical direction that is orthogonal to the first and second directions D1 and D2, which may be horizontal directions.

The second gate stack GST2 may be provided on the first gate stack GST1. The second gate stack GST2 may include the insulating and conductive patterns IP and CP, which are alternately stacked on top of each other in the third direction D3.

The insulating patterns IP may include an insulating material. As an example, the insulating patterns IP may be formed of or include at least one of oxide materials. The conductive patterns CP may include a conductive material. In various example embodiments, the conductive patterns CP may be formed of or include tungsten.

The number of the gate stacks GST1 and GST2 may not be limited to that in the illustrated example. In various example embodiments, the number of the gate stacks GST1 and GST2 may be greater than three, and may or may not be the same as each other.

The numbers of the insulating and conductive patterns IP and CP, which are included in each of the first and second gate stacks GST1 and GST2, may not be limited to those in the illustrated example.

The memory channel structures CS may be extended in the third direction D3 to penetrate the insulating and conductive patterns IP and CP of the first gate stack GST1, the insulating and conductive patterns IP and CP of the second gate stack GST2, and the third and second source layers SL3 and SL2 of the source structure SST.

Each of the memory channel structures CS may include an insulating capping layer 189, a memory channel layer 187 enclosing the insulating capping layer 189, and a memory layer 183 enclosing the memory channel layer 187.

The insulating capping layer 189 may include an insulating material. In various example embodiments, the insulating capping layer 189 may be formed of or include at least one of oxide materials. The memory channel layer 187 may include a conductive material. In various example embodiments, the memory channel layer 187 may be formed of or include polysilicon. The memory channel layer 187 may be electrically connected to the second source layer SL2. The second source layer SL2 may be provided to penetrate the memory layer 183 and may be connected to the memory channel layer 187.

The memory layer 183 may be configured to store data. In various example embodiments, the memory layer 183 may include a tunnel insulating layer enclosing the memory channel layer 187, a data storing layer enclosing the tunnel insulating layer, and a blocking layer enclosing the data storing layer. In various example embodiments, the tunnel insulating layer and the blocking layer may be formed of or include at least one of various oxide materials, and the data storing layer may be formed of or include at least one of nitride materials.

Each of the memory channel structures CS may further include a memory channel pad 185, which is provided on the memory channel layer 187. The memory channel pad 185 may include a conductive material. In various example embodiments, the memory channel pad 185 may be formed of or include polysilicon and/or a metal.

The gate division structures GDS may be extended in the third direction D3 to penetrate the first and second gate stacks GST1 and GST2. The gate division structures GDS may be extended in the second direction D2. The gate division structures GDS may be spaced apart from each other in the first direction D1. The gate division structures GDS may include an insulating material. In various example embodiments, the gate division structures GDS may further include a conductive material, which is provided in the insulating material and is electrically connected to the source structure SST.

The selection line structure EST may include a first selection insulating layer EI1 on the second gate stack GST2 and the gate division structure GDS, a second selection insulating layer EI2 on the first selection insulating layer EI1, a selection line EL on the second selection insulating layer EI2, a third selection insulating layer EI3 on the selection line EL, and selection division structures EDS penetrating the selection line EL.

The first and second selection insulating layers EI1 and EI2 may be formed of or include different insulating materials from each other. For example, there may not be a common material between the first and second insulating materials. In various example embodiments, the first selection insulating layer EI1 may be formed of or include at least one of various nitride materials and may not include an oxide material, and the second selection insulating layer EI2 may be formed of or include at least one of various oxide materials, and may not include a nitride material.

The selection line EL may be or may correspond to a string selection line. The selection line EL may include a conductive material. In various example embodiments, the selection line EL may be formed of or include polysilicon. The third selection insulating layer EI3 may include an insulating material. In various example embodiments, the third selection insulating layer EI3 may be formed of or include at least one of various oxide materials.

The selection division structure EDS may be extended in the second direction D2. The selection division structure EDS may be overlapped with the gate division structure GDS in the third direction D3. The selection division structure EDS may include an insulating material. In various example embodiments, the selection division structure EDS may be formed of or include at least one of various oxide materials.

The selection channel structure EC may be enclosed by the selection line structure EST. The selection channel structure EC may be provided to penetrate the selection line structure EST. The selection channel structure EC may be disposed in the selection line structure EST.

The cover insulating layer 120 may be disposed on the third selection insulating layer EI3 of the selection line structure EST. The cover insulating layer 120 may include an insulating material. In various example embodiments, the cover insulating layer 120 may be formed of or include at least one of various oxide materials.

The bit line contacts 130 may be provided to penetrate the cover insulating layer 120. The bit line contact 130 may be electrically connected to the memory channel structure CS through the selection channel structure EC. The bit line contact 130 may be formed of or include at least one of conductive materials.

The bit line 140 may be provided on the cover insulating layer 120. The bit line 140 extend in the first direction D1. The bit line 140 may be electrically connected to the memory channel structure CS through the bit line contact 130 and the selection channel structure EC. The bit line 140 may be formed of or include at least one of various conductive materials.

The number and/or the arrangement or disposition of the bit line contacts 130, which are connected to the bit line 140, are not limited to the illustrated example. In various example embodiments, each bit line 140 may be connected to one of the bit line contacts 130 between an adjacent pair of the gate division structures GDS.

Referring to FIG. 2C, the selection channel structure EC may include a selection channel layer 150, a selection insulating structure 160 enclosing the selection channel layer 150, and a selection channel pad 170 on the selection channel layer 150.

The selection insulating structure 160 may include a first selection insulating pattern 161 enclosing the selection channel layer 150, a second selection insulating pattern 162 enclosing the first selection insulating pattern 161, and a third selection insulating pattern 163 enclosing the second selection insulating pattern 162. The first and third selection insulating patterns 161 and 163 may include an insulating material that is different from the second selection insulating pattern 162. For example, there may not be a common material between the first and third insulating patterns 161 and 163. In various example embodiments, the first and third selection insulating patterns 161 and 163 may be formed of or include at least one of various oxide materials and may not include a nitride material, and the second selection insulating pattern 162 may be formed of or include at least one of various nitride materials and may not include an oxide material.

The first selection insulating pattern 161 may include a lower portion 161_L, which is enclosed by the second selection insulating layer EI2, and an upper portion 161_U, which is enclosed by the selection line EL and the third selection insulating layer EI3. An outer side surface of the lower portion 161_L of the first selection insulating pattern 161 may be in contact with a side surface of the second selection insulating layer EI2. An outer side surface of the upper portion 161_U of the first selection insulating pattern 161 may be in contact with an inner side surface of the second selection insulating pattern 162.

The selection channel layer 150 may be electrically connected to the memory channel layer 187 of the memory channel structure CS. The selection channel layer 150 may be disposed on the memory channel structure CS. The selection channel layer 150 may include a connecting portion 151 on the memory channel layer 187 of the memory channel structure CS and a pillar portion 152 on the connecting portion 151. The selection channel layer 150 may include a conductive material. In various example embodiments, the selection channel layer 150 may be formed of or include polysilicon.

The connecting portion 151 may be disposed in the first selection insulating layer EI1. The connecting portion 151 may be surrounded by the first selection insulating layer EI1. A side surface of the connecting portion 151 may be in contact with a side surface of the first selection insulating layer EI1. The connecting portion 151 may be disposed at the same level as the first selection insulating layer EI1. A top surface 151_T of the connecting portion 151 may be coplanar with a top surface EI1_T of the first selection insulating layer EI1, which may or may not be in the plane formed by the first direction D1 and the second direction D2. A level of the top surface 151_T of the connecting portion 151 may be equal to a level of the top surface EI1_T of the first selection insulating layer EI1. The top surface 151_T of the connecting portion 151 may be in contact with a bottom surface EI2_B of the second selection insulating layer EI2. The connecting portion 151 may have a shape of a circular plate; however, example embodiments are not limited thereto.

The pillar portion 152 may have a pillar shape. The pillar portion 152 may include a lower portion 152_L and an upper portion 152_U. The lower portion 152_L of the pillar portion 152 may be surrounded by the second selection insulating layer EI2. The lower portion 152_L of the pillar portion 152 may be disposed at the same level as the second selection insulating layer EI2. A side surface of the lower portion 152_L of the pillar portion 152 may be in contact with an inner side surface of the lower portion 161_L of the first selection insulating pattern 161. A boundary between the connecting portion 151 and the lower portion 152_L of the pillar portion 152 may be formed or arranged at the same level as the top surface 151_T of the connecting portion 151, the top surface EI1_T of the first selection insulating layer EI1, and the bottom surface EI2_B of the second selection insulating layer EI2. The upper portion 152_U of the pillar portion 152 may be enclosed by the selection line EL and the third selection insulating layer EI3. A side surface of the upper portion 152_U of the pillar portion 152 may be in contact with an inner side surface of the upper portion 161_U of the first selection insulating pattern 161. A bottom surface 152_UB of the upper portion 152_U of the pillar portion 152 may be in contact with a top surface 161_LT of the lower portion 161_L of the first selection insulating pattern 161. A boundary between the lower and upper portions 152_L and 152_U of the pillar portion 152 may be located at substantially the same level as a bottom surface EL_B of the selection line EL and a top surface EI2_T of the second selection insulating layer EI2.

A width of the connecting portion 151 may be greater than a width of the pillar portion 152. As an example, a width of the connecting portion 151 in the first direction D1 may be greater than a width of the pillar portion 152 in the first direction D1. The width of the connecting portion 151 may be larger than a width of the lower portion 152_L of the pillar portion 152. As an example, the width of the connecting portion 151 in the first direction D1 may be larger than a width of the lower portion 152_L of the pillar portion 152 in the first direction D1. A width of the upper portion 152_U of the pillar portion 152 may be greater than the width of the lower portion 152_L of the pillar portion 152. As an example, a width of the upper portion 152_U of the pillar portion 152 in the first direction D1 may be greater than the width of the lower portion 152_L of the pillar portion 152 in the first direction D1.

In some example embodiments, the selection channel layer 150 including the connecting portion 151 and the pillar portion 152 may have a polycrystalline structure. In some example embodiments, a size of a grain of the polycrystalline components of the selection channel structure 150 may correspond to one or more of a volume of the grain and/or a largest linear dimension of the grain. In some example embodiments, an average size of the grains in the selection channel layer 150 may be measured, e.g., with an analytical technique such as but not limited to transmission electron microscopy (TEM) and/or x-ray diffraction (XRD) techniques. In some example embodiments, the average grain size may correspond to a measure of central tendency, such as but not limited to an arithmetic mean and/or an arithmetic median and/or an arithmetic mode of grain sizes, and/or a function of one or more thereof; example embodiments are not limited thereto.

An average size of grains or crystalline grains in the selection channel layer 150 may increase as a level is elevated. An average size of grains in the connecting portion 151 may be smaller than an average size of grains in the pillar portion 152. The average size of the grains in the connecting portion 151 may be smaller than a mean size of grains in the lower portion 152_L of the pillar portion 152. The average size of the grains in the lower portion 152_L of the pillar portion 152 may be smaller than a mean size of grains in the upper portion 152_U of the pillar portion 152.

The pillar portion 152 of the selection channel layer 150 may overlap with or surround or be disposed at a center of the selection channel structure EC. For example, the pillar portion 152 of the selection channel layer 150 may be disposed at a center of the selection channel structure EC, when viewed in a plan view. A center line C of the selection channel structure EC may be overlapped with or be surrounded by the connecting and pillar portions 151 and 152 of the selection channel layer 150 and the selection channel pad 170 in the third direction D3. The connecting and pillar portions 151 and 152 of the selection channel layer 150 and the selection channel pad 170 may be arranged along the center line C of the selection channel structure EC.

A bottom surface of the third selection insulating pattern 163 may be in contact with the top surface EI2_T of the second selection insulating layer EI2. A bottom surface of the lower portion 161_L of the first selection insulating pattern 161 may be in contact with the top surface 151_T of the connecting portion 151.

In various example embodiments, the selection channel layer 150 may have the same crystal orientation as the memory channel pad 185 of the memory channel structure CS. For example, grains in the selection channel layer 150 may have the same crystal orientation as grains in the memory channel pad 185.

The selection channel pad 170 may be surrounded by the selection insulating structure 160. A side surface of the selection channel pad 170 may be in contact with the inner side surface of the upper portion 161_U of the first selection insulating pattern 161. In various example embodiments, the selection channel layer 150 and the selection channel pad 170 may be provided to completely fill a space, which is enclosed by the selection insulating structure 160.

The selection channel pad 170 may include a conductive material. An impurity concentration of the selection channel pad 170 may be higher than an impurity concentration of the selection channel layer 150. In various example embodiments, the selection channel pad 170 and the selection channel layer 150 may include polysilicon, and the selection channel pad 170 may further contain phosphorus (P) or boron (B).

In the semiconductor device according to various example embodiments of inventive concepts, a grain size of the selection channel layer 150 may not be irregular, and a mean size of grains in the selection channel layer 150 may increase with increasing vertical level. Accordingly, it may be possible to improve uniformity of the grain size of the selection channel layer 150 and to improve uniformity of critical voltages for the selection channel structure EC and the selection line EL.

In the semiconductor device according to various example embodiments of inventive concepts, since the selection channel layer 150 has the pillar shape, grains in the selection channel layer 150 may have a relatively large grain size, and thus, the channel current characteristics of the selection channel layer 150 may be improved.

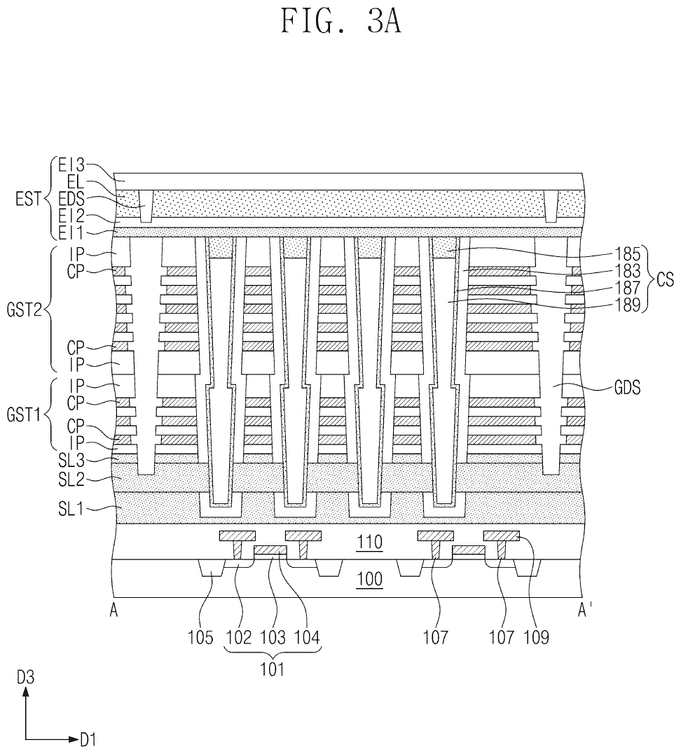

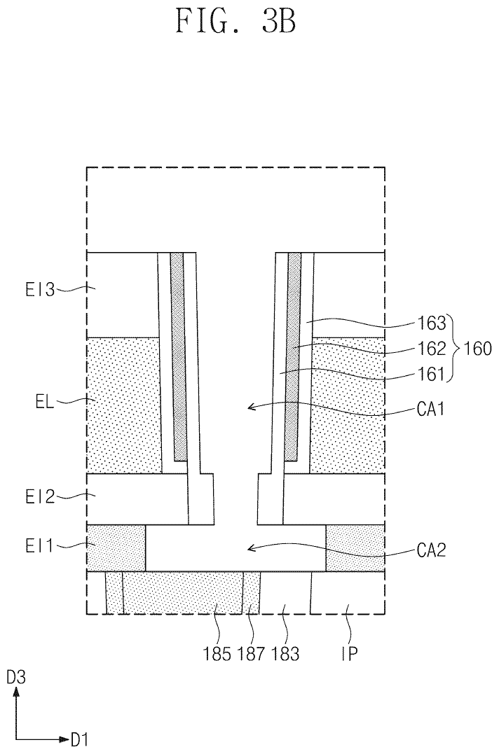

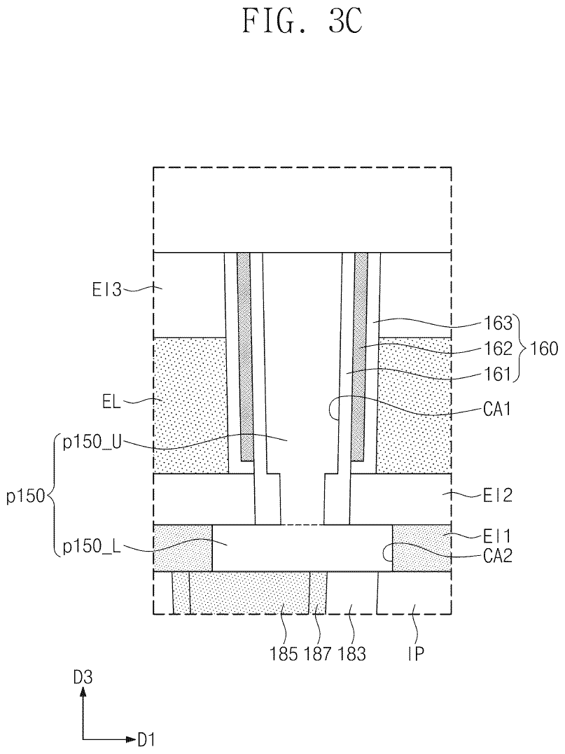

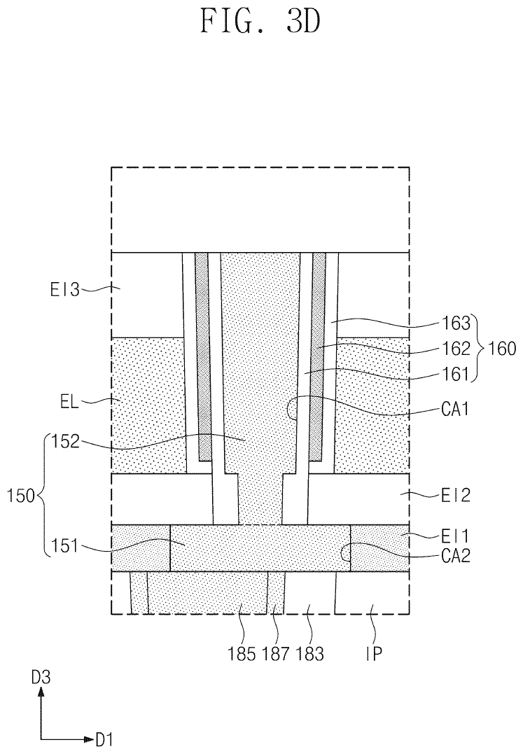

FIGS. 3A, 3B, 3C, and 3D are diagrams illustrating a method of fabricating a semiconductor device, according to various example embodiments of inventive concepts.

Referring to FIG. 3A, the peripheral transistor 101 and the device isolation layer 105 may be formed on the substrate 100. The peripheral circuit insulating layer 110, the peripheral contact 107, and the peripheral conductive line 109 may be formed.

The first source layer SL1, a preliminary source layer, and the third source layer SL3 may be sequentially formed on the peripheral circuit insulating layer 110. The preliminary source layer may be formed of or include an insulating material. A first stack may be formed on the third source layer SL3, and a second stack may be formed on the first stack. Each of the first and second stacks may include stacked-insulating layers and stacked-sacrificial layers, which are alternately stacked on top of each other. The stacked-insulating layer and the stacked-sacrificial layer may be formed of or include different insulating materials from each other. In various example embodiments, the stacked-insulating layers may be formed of or include oxide, and the stacked-sacrificial layers may be formed of or include nitride.

The memory channel structure CS may be formed to penetrate the first and second stacks. The formation of the memory channel structure CS may include forming the memory layer 183, forming the memory channel layer 187 in the memory layer 183, and forming the insulating capping layer 189 and the memory channel pad 185 in the memory channel layer 187.

The second source layer SL2, the conductive pattern CP, and the gate division structure GDS may be formed. The formation of the second source layer SL2, the conductive pattern CP, and the gate division structure GDS may include forming a trench to penetrate the first stack and the second stack, replacing the preliminary source layer with the second source layer SL2 through the trench, replacing the stacked-sacrificial layer with the conductive pattern CP through the trench, and forming the gate division structure GDS to fill the trench.

The replacing of the preliminary source layer with the second source layer SL2 may include removing the preliminary source layer and forming the second source layer SL2 in an empty space, which is formed by removing the preliminary source layer. The replacing of the stacked-sacrificial layer with the conductive pattern CP may include removing the stacked-sacrificial layer and forming the conductive pattern CP in an empty space, which is formed by removing the stacked-sacrificial layer. In various example embodiments, the second source layer SL2 may be formed after the formation of the conductive pattern CP.

The stacked-insulating layer, which is pierced by the memory channel structure CS and the gate division structure GDS, may be defined as the insulating pattern IP. The first gate stack GST1, which includes the insulating and conductive patterns IP and CP, may be defined. The second gate stack GST2, which includes the insulating and conductive patterns IP and CP, may be defined.

The selection line structure EST may be formed on the second gate stack GST2. The formation of the selection line structure EST may include sequentially forming the first selection insulating layer EI1, the second selection insulating layer EI2, and the selection line EL, forming the selection division structures EDS to penetrate the selection line EL, and forming the third selection insulating layer EI3 on the selection line EL.

Referring to FIG. 3B, the selection insulating structure 160, which is enclosed by the selection line structure EST, may be formed. In various example embodiments, the formation of the selection insulating structure 160 may include etching the third selection insulating layer EI3 and the selection line EL, forming a first preliminary insulating layer to enclose the etched third selection insulating layer EI3 and the etched selection line EL, forming a second preliminary insulating layer on the first preliminary insulating layer, etching the first preliminary insulating layer, the second preliminary insulating layer, and the second selection insulating layer EI2, forming a third preliminary insulating layer on the etched second preliminary insulating layer and the etched second selection insulating layer EI2, and etching the third preliminary insulating layer. The etched first preliminary insulating layer may be defined as the third selection insulating pattern 163, the etched second preliminary insulating layer may be defined as the second selection insulating pattern 162, and the etched third preliminary insulating layer may be defined as the first selection insulating pattern 161.

A first cavity CA1, which is enclosed by the first selection insulating pattern 161, may be defined. The first cavity CA1 may be enclosed by the second selection insulating layer EI2, the selection line EL, and the third selection insulating layer EI3. The first selection insulating layer EI1 may be formed through the first cavity CA1. In various example embodiments, the first selection insulating layer EI1 may be etched through a pull-back process. A second cavity CA2 may be formed by the etching of the first selection insulating layer EI1. The second cavity CA2 may be enclosed by the first selection insulating layer EI1. The memory channel pad 185 may be exposed through the second cavity CA2.

Referring to FIG. 3C, a preliminary selection channel layer p150, which is enclosed by the selection insulating structure 160, may be formed. The preliminary selection channel layer p150 may include a lower portion p150_L and an upper portion p150_U, which are respectively provided in the second cavity CA2 and in the first cavity CA1. The lower portion p150_L of the preliminary selection channel layer p150 may be enclosed by the first selection insulating layer EI1. The upper portion p150_U of the preliminary selection channel layer p150 may be enclosed by the selection insulating structure 160. The upper portion p150_U of the preliminary selection channel layer p150 may be enclosed by the second selection insulating layer EI2, the selection line EL, and the third selection insulating layer EI3. The preliminary selection channel layer p150 may be formed of or include a material, which can form the selection channel layer 150 of FIG. 2C when melted and solidified. In various example embodiments, the preliminary selection channel layer p150 may be formed of or include amorphous silicon.

In various example embodiments, a seam may be formed in the preliminary selection channel layer p150.

Referring to FIG. 3D, the selection channel layer 150 may be formed. The formation of the selection channel layer 150 may include melting the preliminary selection channel layer p150 and solidifying the melted preliminary selection channel layer p150. The melting of the preliminary selection channel layer p150 may be performed using, for example, a laser beam. The lower portion p150_L of the preliminary selection channel layer p150 may be melted and solidified to form the connecting portion 151 of the selection channel layer 150. The upper portion p150_U of the preliminary selection channel layer p150 may be melted (e.g., with a selective laser melting process) and solidified to form the pillar portion 152 of the selection channel layer 150. As a result of the melting and solidifying steps, the selection channel layer 150 may be crystallized, or formed with polycrystalline structures.

In various example embodiments, a laser beam may be irradiated to the upper portion p150_U of the preliminary selection channel layer p150, and thus, in the melting step, the temperature of the upper portion p150_U of the preliminary selection channel layer p150 may be increased higher than the temperature of the lower portion p150_L of the preliminary selection channel layer p150. Accordingly, an average or mean size of grains in the solidified connecting portion 151 may be smaller than an average or mean size of grains in the solidified pillar portion 152. Such a difference may be observable on a TEM micrograph and/or on an XRD analysis; example embodiments are not limited thereto.

In various example embodiments, the temperature of the preliminary selection channel layer p150 in the melting step may increase with increasing vertical level, and an average r mean size of grains in the solidified selection channel layer 150 may also increase with increasing vertical level.

In various example embodiments, the memory channel pad 185 may also be melted, when the preliminary selection channel layer p150 is melted. In various example embodiments, the memory channel pad 185 may be used as a heat sink, when the preliminary selection channel layer p150 is solidified, and thus, the selection channel layer 150 may be grown in accordance with a crystal structure of the memory channel pad 185; for example, the selection channel layer 150 may have the same crystal orientation as the memory channel pad 185. In various example embodiments, the preliminary selection channel layer p150 may only be partially melted.

Referring to FIGS. 2A, 2B, and 2c, the selection channel pad 170 may be formed. The formation of the selection channel pad 170 may include injecting impurities into the pillar portion 152 of the selection channel layer 150.

The cover insulating layer 120 may be formed on the selection line structure EST. The bit line contact 130 may be formed to penetrate the cover insulating layer 120. The bit line 140, which is connected to the bit line contact 130, may be formed.

In the fabricating method according to various example embodiments of inventive concepts, the laser beam may be used to selectively heat the preliminary selection channel layer p150, and thus, it may be possible to prevent or suppress the conductive patterns CP from being excessively heated.

In the fabricating method according to various example embodiments of inventive concepts, since the pillar portion 152 of the selection channel layer 150 is formed to have the pillar shape, it may be possible to reduce cost and time for the process of fabricating a semiconductor device.

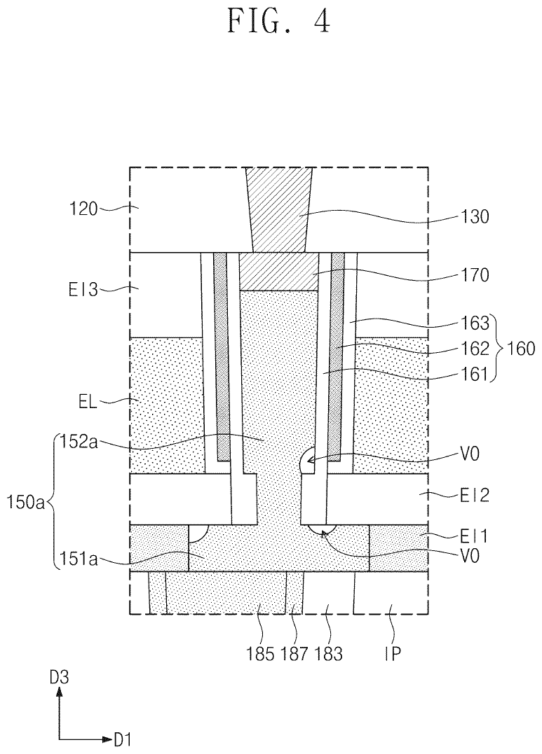

FIG. 4 is an enlarged sectional view illustrating a semiconductor device according to various example embodiments of inventive concepts.

Referring to FIG. 4, the semiconductor device may include or define voids VO. The void VO may be provided in at least one position as illustrated, e.g., in at least one of between the pillar portion 152a of the selection channel layer 150a and the first selection insulating pattern 161, between the connecting portion 151a of the selection channel layer 150a and the first selection insulating pattern 161, or between the connecting portion 151a of the selection channel layer 150a and the second selection insulating layer EI2.

Due to the melting and solidifying steps, the voids VO may be formed in the process of forming the selection channel layer 150a. The void VO may be formed on the second selection insulating layer EI2 and the first selection insulating pattern 161 which both contain an oxide material and thus have a relatively high interface energy.

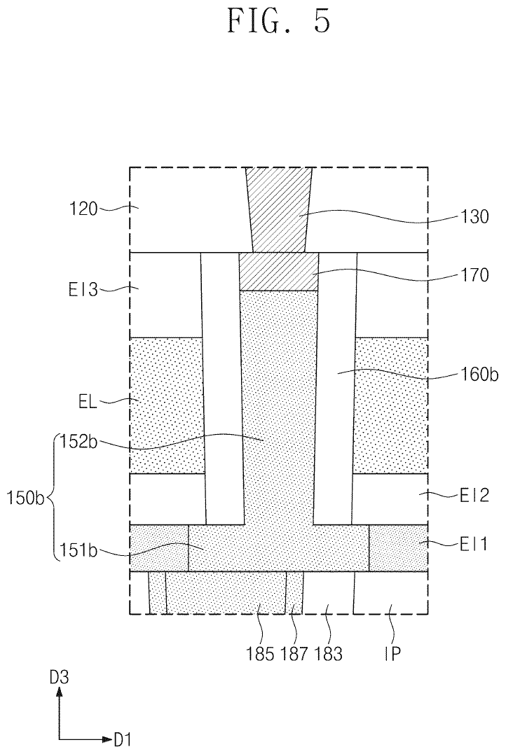

FIG. 5 is an enlarged sectional view illustrating a semiconductor device according to various example embodiments of inventive concepts.

Referring to FIG. 5, the selection insulating structure 160b of the semiconductor device may be a single insulating layer. As an example, the selection insulating structure 160b may be a single oxide layer. The second selection insulating layer EI2b may be in contact with an outer side surface of the selection insulating structure 160b. The pillar portion 152b of the selection channel layer 150b may be in contact with an inner side surface of the selection insulating structure 160b. The connecting portion 151b of the selection channel layer 150b may be in contact with a bottom surface of the selection insulating structure 160b.

In a semiconductor device and an electronic system according to various example embodiments of inventive concepts, grains in a selection channel layer may have a regular size, and thus, it may be possible to improve uniformity of critical voltages for a selection channel structure and a selection line.

While various example embodiments of inventive concepts have been particularly shown and described, it will be understood by one of ordinary skill in the art that variations in form and detail may be made therein without departing from the spirit and scope of the attached claims. In addition example embodiments are not necessarily mutually exclusive with one another. For example, some example embodiments may include one or more features described with reference to one or more figures, and may also include one or more other features described with reference to one or more other figures.

What is claimed is:

1. A semiconductor device, comprising:
a gate stack including insulating and conductive patterns, which are alternately stacked on top of each other;
a memory channel structure penetrating the gate stack;
a selection line structure on the gate stack; and
a selection channel structure penetrating the selection line structure,
wherein the memory channel structure comprises an insulating capping layer, a memory channel layer enclosing the insulating capping layer, and a memory layer enclosing the memory channel layer,
the selection channel structure comprises a selection channel layer electrically connected to the memory channel layer, and a selection insulating structure enclosing the selection channel layer,
the selection channel layer comprises a connecting portion on the memory channel structure and a pillar portion on the connecting portion, and
an average size of grains in the connecting portion is less than an average size of grains in the pillar portion.

2. The semiconductor device of claim 1, wherein the selection channel layer comprises polysilicon.

3. The semiconductor device of claim 1, wherein a width of the connecting portion is larger than a width of a lower portion of the pillar portion.

4. The semiconductor device of claim 1, wherein
the selection line structure comprises a first selection insulating layer on the gate stack, a second selection insulating layer on the first selection insulating layer, and a selection conductive line on the second selection insulating layer, and
the first selection insulating layer and the second selection insulating layer comprise different insulating materials from each other.

5. The semiconductor device of claim 4, wherein
the connecting portion is enclosed by the first selection insulating layer, and
the pillar portion is enclosed by the second selection insulating layer and by the selection conductive line.

6. The semiconductor device of claim 1, wherein the pillar portion overlaps with a center of the selection channel structure, when viewed in a plan view.

7. The semiconductor device of claim 1, wherein
the memory channel structure further comprises a memory channel pad on the insulating capping layer, and
the selection channel layer has a same crystal orientation as the memory channel pad.

8. The semiconductor device of claim 1, wherein
the selection channel structure further comprises a selection channel pad on the selection channel layer,
the selection channel pad and the selection channel layer comprise polysilicon, and
an impurity concentration of the selection channel pad is greater than an impurity concentration of the selection channel layer.

9. The semiconductor device of claim 1, wherein
the pillar portion comprises a lower portion on the connecting portion and an upper portion on the lower portion, and
an average size of grains in the lower portion of the pillar portion is smaller than an average size of grains in the upper portion of the pillar portion.

10. A semiconductor device, comprising:
a gate stack including insulating and conductive patterns, which are alternately stacked on top of each other;
a memory channel structure penetrating the gate stack;
a selection line structure on the gate stack; and
a selection channel structure penetrating the selection line structure, wherein
the memory channel structure comprises an insulating capping layer, a memory channel layer enclosing the insulating capping layer, and a memory layer enclosing the memory channel layer,
the selection channel structure comprises a selection channel layer electrically connected to the memory channel layer, and a selection insulating structure enclosing the selection channel layer,
the selection channel layer comprises a connecting portion on the memory channel structure and a pillar portion on the connecting portion, and
the pillar portion overlaps with a center of the selection channel structure.

11. The semiconductor device of claim 10, wherein the pillar portion has a pillar shape.

12. The semiconductor device of claim 10, wherein
the selection channel structure further comprises a selection channel pad on the selection channel layer, and
the selection channel layer and the selection channel pad fill a space that is enclosed by the selection insulating structure.

13. The semiconductor device of claim 10, wherein the selection insulating structure comprises a first selection insulating pattern enclosing the selection channel layer, a second selection insulating pattern enclosing the first selection insulating pattern, and a third selection insulating pattern enclosing the second selection insulating pattern.

14. The semiconductor device of claim 13, wherein the first and third selection insulating patterns comprise an insulating material different from the second selection insulating pattern.

15. The semiconductor device of claim 10, wherein
the selection line structure comprises a first selection insulating layer on the gate stack, a second selection insulating layer on the first selection insulating layer, and a selection conductive line on the second selection insulating layer, and
the first selection insulating layer and the second selection insulating layer comprise different insulating materials from each other.

16. The semiconductor device of claim 15, wherein a top surface of the connecting portion is coplanar with a top surface of the first selection insulating layer.

17. The semiconductor device of claim 16, wherein the top surface of the connecting portion is in contact with a bottom surface of the second selection insulating layer.

18. The semiconductor device of claim 10, wherein the pillar portion is overlapped with a center line of the selection channel structure.

19. An electronic system, comprising:
a main substrate;
a semiconductor device on the main substrate; and
a controller on the main substrate and electrically connected to the semiconductor device,
wherein the semiconductor device comprises,
a gate stack including insulating and conductive patterns, which are alternately stacked on top of each other,
a memory channel structure penetrating the gate stack,
a selection line structure on the gate stack, and
a selection channel structure penetrating the selection line structure, wherein
the memory channel structure comprises an insulating capping layer, a memory channel layer enclosing the insulating capping layer, and a memory layer enclosing the memory channel layer,
the selection channel structure comprises a selection channel layer, which is electrically connected to the memory channel layer, and a selection insulating structure enclosing the selection channel layer,
the selection channel layer comprises a connecting portion on the memory channel structure and a pillar portion on the connecting portion,
the pillar portion overlaps with a center of the selection channel structure, when viewed in a plan view,
a width of the connecting portion is larger than a width of the pillar portion,
the selection channel layer comprises polysilicon, and
an average size of grains in the connecting portion is less than an average size of grains in the pillar portion.

20. The electronic system of claim 19, wherein
the pillar portion comprises a lower portion on the connecting portion and an upper portion on the lower portion, and
an average size of grains in the lower portion of the pillar portion is less than an average size of grains in the upper portion of the pillar portion.
